(19) United States
(12) Patent Application Publication
(10) Pub. No.: US 2009/0065845 A1
(43) Pub. Date: Mar. 12, 2009

(54) Embedded semiconductor device and method of manufacturing an embedded semiconductor device

(75) Inventors: Young-Ho Kim, Hwaseong-si (KR); Hee-Seog Jeon, Suwon-si (KR); Yong-Kyu Lee, Gwacheon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/230,938

(22) Filed: Sep. 8, 2008

(30) Foreign Application Priority Data
Sep. 11, 2007 (KR) 10-2007-0092016

(51) Int. Cl. H01L 27/115; H01L 21/8247

(52) U.S. Cl. 257/316; 257/326; 438/258; 438/287; 257/E27.103; 257/E21.691

(57) ABSTRACT

Provided are an embedded semiconductor device and a method of manufacturing an embedded semiconductor device. In a method of manufacturing the embedded semiconductor device, layers of at least one cell gate stack may be formed in a cell area of a substrate. A logic gate structure may be formed in a logic area of the substrate. First source/drain regions may be formed adjacent to the logic gate structure, and metal silicide patterns may be formed on the logic gate structure and the first source/drain regions. At least one hard mask may be formed on the layers of the at least one cell gate stack, and a blocking pattern may be formed to cover the logic gate structure and the first source/drain regions. The at least one cell gate stack may be formed in the cell area by etching the layers of the at least one cell gate stack using the at least one hard mask as an etching mask. A memory transistor in the cell area may have an increased integration degree and a logic transistor in the logic area may have an increased response speed and a decreased resistance.

### BACKGROUND

1. Field

Example embodiments relate to an embedded semiconductor device and a method of manufacturing an embedded semiconductor device. More particularly, example embodiments relate to an embedded semiconductor device including at least one memory transistor having an increased integration degree and a logic transistor having an increased performance, and a method of manufacturing the embedded semiconductor device including the memory transistor and the logic transistor on one substrate.

2. Description of the Related Art

A semiconductor device has various integrated circuits which are provided on a substrate through a deposition process and/or an etching process. As for a semiconductor memory device, each of memory cells in the memory device may store data as the logic of “0” or “1”. The semiconductor memory devices are usually classified into a volatile memory device and a non-volatile memory device. The volatile memory device may lose stored data when the applied power is off, whereas the non-volatile memory device may maintain data stored therein even though the applied power is off.

A flash memory device, one of the non-volatile memory devices, may electrically store data into memory cells thereof and may erase the stored data from the memory cells. Although power is not applied to the memory cell of the flash memory device, the data stored in the memory cell may be maintained. Further, stored data in a section or a block of the memory cells may be simultaneously erased by applying a predetermined or given voltage to an input of the flash memory device. Thus, the flash memory device may be widely employed in various applications, e.g., a memory card, a memory stick, a computer, a digital camera, an MP3 player and/or a cellular phone.

Recently, a flash embedded logic device has been developed for various applications of the flash memory device. In the flash embedded logic device, flash memory cells and a logic element may be provided on one substrate. For example, flash memory cells may be arranged in one area of the substrate, and the logic element electrically connected to the flash memory cells may be positioned in another area of the substrate. The logic element may include a transistor, a diode, a bandgap device, a capacitor and/or an inductor.

However, processes for manufacturing the flash embedded logic device may be difficult in comparison with the conventional flash memory device. Therefore, a failure of the flash embedded logic device may often occur in manufacturing processes thereof, and electrical characteristics of a flash memory cell and the logic element may not be desirably controlled. For example, various gate structures of the flash memory cell and the logic element may not be easily formed on one substrate because the flash memory cell has a construction different from that of the logic element and one flash memory cell has a width different from another flash memory cell.

Metal silicide patterns may be provided on a gate electrode and source/drain regions of the logic element so as to improve electrical characteristics of the logic element, e.g., a logic transistor. However, a gate mask may be disposed on the gate electrode of the logic transistor, so that the process for forming the metal silicide patterns may be complicated because of the gate mask. Although a photoresist pattern is formed on the gate electrode as an etching mask for forming the gate electrode, the gate electrode may not have a desired width and a proper profile because the photoresist pattern has is relatively weak in strength or weak endurance. As described above, providing flash memory cells and a logic element on one substrate while simultaneously ensuring desired profile and electrical characteristics of the flash memory cells and the logic element may be difficult.

### SUMMARY

This application claims priority under 35 U.S.C. §119 to Korean Patent Application No. 2007-92016, filed on Sep. 11, 2007, in the Korean Intellectual Property Office (KIPO), the entire contents of which are herein incorporated by reference.

Example embodiments provide an embedded semiconductor device including a memory transistor having a minute or reduced width and a logic transistor having an increased response speed. Example embodiments provide a method of manufacturing an embedded semiconductor device including a memory transistor of a minute or reduced width and a logic transistor of an increased response speed on one substrate.

According to example embodiments, an embedded semiconductor device may include at least one cell gate stack in a cell area of a substrate, at least one hard mask on the at least one cell gate stack, a logic gate structure in a logic area of the substrate, first source/drain regions adjacent to the logic gate structure, metal silicide patterns on the logic gate structure and the first source/drain regions, and a blocking pattern covering the logic gate structure and the first source/drain regions.

In example embodiments, the at least one cell gate stack may include a first cell gate stack having a memory gate structure and a second cell gate stack having a selection gate structure. The memory gate structure may have a width smaller than a width of the selection gate structure. The memory gate structure may include a floating gate, a first dielectric layer pattern and a control gate. The selection gate structure may include a first cell gate electrode, a second dielectric layer pattern and a second cell gate electrode.

In example embodiments, the first cell gate stack may further include a first tunnel insulation layer pattern beneath the memory gate structure, a first cell metal silicide pattern on the memory gate structure and a first hard mask on the first cell metal silicide pattern. The second cell gate stack may further include a second tunnel insulation layer pattern beneath the selection gate structure, a second cell metal silicide pattern on the selection gate structure and a second hard mask on the second cell metal silicide pattern.

In example embodiments, the logic gate structure may have a height smaller than a height of the at least one cell gate stack. The logic gate structure may include a gate insulation layer pattern and a logic gate electrode. In example embodiments, the at least one cell gate stack may include a tunnel insulation layer pattern, a charge trapping layer pattern, a dielectric layer pattern and a control gate. In example embodiments, the blocking pattern may include a material substantially the same as a material of the at least one hard mask.

In example embodiments, the embedded semiconductor device may further include second source/drain regions adjacent to the at least one cell gate stack. In example embodiments, the embedded semiconductor device may further include a cell gate spacer on a sidewall of the at least one cell gate stack, and a logic gate spacer on a sidewall of the logic gate structure. First source/drain extension regions may be disposed beneath the logic gate spacer, and second source/drain extension regions may be provided beneath the cell gate spacer.

According to example embodiments, there is provided a method of manufacturing an embedded semiconductor device. In the method, layers of at least one cell gate stack may be formed in a cell area of a substrate. A logic gate structure may be formed in a logic area of the substrate. First source/drain regions may be formed adjacent to the logic gate structure. Metal silicide patterns may be formed on the logic gate structure and the first source/drain regions. At least one hard mask may be formed on the layers of at least one cell gate stack, and a blocking pattern may be formed to cover the logic gate structure and the first source/drain regions. The at least one cell gate stack may be formed in the cell area by etching the layers of at least one cell gate stack using the at least one hard mask as an etching mask.

In forming the layers of the at least one cell gate stack according to example embodiments, a tunnel insulation layer may be formed on the substrate. A first conductive layer may be formed on the tunnel insulation layer. A dielectric layer may be formed on the first conductive layer. Portions of the dielectric layer, the first conductive layer and the tunnel insulation layer may be removed from the logic area of the substrate. A gate insulation layer may be formed in the logic area, and a second conductive layer may be formed on a remaining dielectric layer and the gate insulation layer. In example embodiments, an opening exposing the first conductive layer may be formed by partially removing the remaining dielectric layer before forming the second conductive layer.

In forming the at least one hard mask and forming the at least one cell gate stack according to example embodiments, a first hard mask and a second hard mask may be formed on the second conductive layer in the cell area. A first cell gate stack and a second cell gate stack may be formed by etching the second conductive layer, the dielectric layer, the first conductive layer and the tunnel insulation layer using the first and the second hard masks as etching masks. The first cell gate stack may include a first tunnel insulation layer pattern, a floating gate, a first dielectric layer pattern and a control gate. The second cell gate stack may include a second tunnel insulation layer pattern, a first cell gate electrode, a second dielectric layer pattern and a second cell gate electrode.

In example embodiments, a first cell metal silicide pattern may be formed on the control gate, and a second cell metal silicide pattern may be formed on the second cell gate electrode. A first cell gate spacer may be formed on a sidewall of the first cell gate stack, and a second cell gate spacer may be formed on a sidewall of the second cell gate stack.

In forming the at least one hard mask and forming the at least one cell gate stack according to example embodiments, at least one hard mask may be formed on the second conductive layer in the cell area. The at least one cell gate stack may be formed by etching the second conductive layer, the dielectric layer, the first conductive layer and the tunnel insulation layer using the at least one hard mask as an etching mask. The at least one cell gate stack may include a tunnel insulation layer pattern, a charge trapping layer pattern, a dielectric layer pattern and a control gate.

In forming the logic gate structure according to example embodiments, a photoresist pattern may be formed on the second conductive layer in the logic area. A gate insulation layer pattern and a logic gate electrode may be formed by etching the second conductive layer and the gate insulation layer using the photoresist pattern as an etching mask.

In example embodiments, the at least one hard mask and the blocking pattern may be simultaneously formed. In forming the at least one hard mask and forming the blocking pattern, a hard mask layer may be formed on the layers of at least one cell gate stack and the logic gate structure. A photoresist pattern may be formed on the hard mask layer, and then the hard mask layer may be etched using the photoresist pattern as an etching mask. In example embodiments, second source/drain regions may be further formed adjacent to the at least one cell gate stack.

According to example embodiments, the embedded semiconductor device may include at least one memory transistor having a minute or reduced width and a logic transistor having an increased response speed and a decreased resistance, so that the embedded semiconductor device may have an improved integration degree and enhanced electrical characteristics. Further, the memory transistor and the logic transistor may be more easily formed on one substrate, so that productivity of the embedded semiconductor device may be improved while reducing the manufacturing cost and time for the embedded semiconductor device.

### BRIEF DESCRIPTION OF THE DRAWINGS

Example embodiments will be more clearly understood from the following detailed description taken in conjunction with the accompanying drawings. FIGS. 1-15 represent non-limiting, example embodiments as described herein.

FIG. 1 is a cross-sectional view illustrating an embedded semiconductor device in accordance with example embodiments;

FIGS. 2 to 14 are cross-sectional views illustrating a method of manufacturing an embedded semiconductor device in accordance with example embodiments; and

FIG. 15 is a cross-sectional view illustrating an embedded semiconductor device in accordance with example embodiments.

It should be noted that these Figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION OF EXAMPLE EMBODIMENTS

Example embodiments are described more fully hereinafter with reference to the accompanying drawings. Example embodiments may, however, be embodied in many different forms and should not be construed as limited to example embodiments set forth herein. Rather, these example embodiments are provided so that this disclosure will be thorough and complete, and will fully convey the scope of example embodiments to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIG. 1 is a cross-sectional view illustrating an embedded semiconductor device in accordance with example embodiments. The embedded semiconductor device illustrated in FIG. 1 may include a unit cell of an EEPROM device and a logic transistor for a logic circuit. The unit cell of the EEPROM device may have two cell transistors, e.g., a memory transistor and a selection transistor. In FIG. 1, “1” indicates a cell area of a substrate 100 and “II” denotes a logic area of the substrate 100.

Referring to FIG. 1, the embedded semiconductor device may be provided on the substrate 100 having the cell area I and the logic area II. The cell transistors of the embedded semiconductor device may be formed in the cell area I and the logic circuit may be provided in the logic area II. The substrate 100 may include a semiconductor substrate, e.g., a silicon substrate, a germanium substrate and/or a silicon-germanium substrate. Alternatively, the substrate 100 may include a silicon-on-insulator (SOI) substrate or a germanium-on-insulator (GOI) substrate.

The unit cells of the EEPROM having two transistors may be provided in the cell area I. For example, the memory transistor and the selection transistor may be formed on the cell area I. The memory transistor may store data therein and the selection transistor may select a corresponding memory cell. The memory transistor may be electrically connected to the selection transistor in parallel.

The cell area I of the substrate 100 may be divided into an isolation region and an active region by an isolation layer 101. The memory and the selection transistors may be formed in the cell area I of the substrate 100. The memory transistor may include a first cell gate stack 131 and the selection transistor may include a second cell gate stack 132. The first cell gate stack 131 and the second cell gate stack 132 may be disposed in the active region of the cell area I. The first and the second cell gate stacks 131 and 132 may be employed in the memory and the selection transistors. Each of the first and the second cell gate stacks 131 and 132 may extend along on the substrate 100 as a line shape or a bar shape. Adjacent first and second cell gate stacks 131 and 132 may be arranged in parallel.

The first cell gate stack 131 may include a first tunnel insulation layer pattern 102a, a memory gate structure 140a, a first cell metal silicide pattern 125a, a first hard mask 126a, and a first cell gate spacer 135. The memory gate structure 140a may include a floating gate 104a, a first dielectric layer pattern 106a and a control gate 110a. The memory gate structure 140a may serve as a sense line of the embedded semiconductor device. The second cell gate stack 132 may include a second tunnel insulation layer pattern 102b, a selection gate structure 140b, a second cell metal silicide pattern 125b, a second hard mask 126b and a second cell gate spacer 136. The selection gate structure 140b may include a first cell gate electrode 104b, a second dielectric layer pattern 106b and a second cell gate electrode 110b. The second cell gate electrode 110b may be connected to the first cell gate electrode 104b by an opening formed through the second dielectric layer pattern 106b. The selection gate structure 140b may serve as a word line of the embedded semiconductor device.

The first and the second tunnel insulation layer patterns 102a and 102b may be disposed on the active region of the cell area I. The first and the second tunnel insulation layer patterns 102a and 102b may include silicon oxide formed by a thermal oxidation process. Alternatively, each of the first and the second tunnel insulation layer patterns 102a and 102b may include a metal oxide, for example, hafnium oxide (HfOx), zirconium oxide (ZrOx), aluminum oxide (AlOx), tantalum oxide (TaOx) and/or titanium oxide (TiOx).

The floating gate 104a and the first cell gate electrode 104b may be located on the first tunnel insulation layer pattern 102a and the second tunnel insulation layer pattern 102b, respectively. The floating gate 104a and the first cell gate electrode 104b may include polysilicon doped with impurities, a metal and/or a metal compound. Examples of the metal in the floating gate 104a and the first cell gate electrode 104b may include tungsten (W), aluminum (Al), titanium (Ti), tantalum (Ta) and/or copper (Cu). Examples of the metal compound in the floating gate 104a and the first cell gate electrode 104b may include titanium nitride (TiNx), aluminum nitride (AlNx), titanium aluminum nitride (TiAlxNy), tungsten nitride (WNx) and/or tantalum nitride (TaNx).

The first and the second dielectric layer patterns 106a and 106b may be positioned on the floating gate 104a and the first cell gate electrode 104b. Each of the first and the second dielectric layer patterns 106a and 106b may include a nitride or a metal compound having a high dielectric constant. For example, the first and the second dielectric layer patterns 106a and 106b may include silicon nitride, hafnium oxide, zirconium oxide, tantalum oxide, titanium oxide and/or aluminum oxide. Alternatively, the first and the second dielectric layer patterns 106a and 106b may have oxide/nitride/oxide (ONO) structures, respectively.

The control gate 110a and the second cell gate electrode 110b may be located on the first dielectric layer pattern 106a and the second dielectric layer pattern 106b. The control gate 110a and the second cell gate electrode 110b may include doped polysilicon, a metal and/or a metal compound. For example, each of the control gate 110a and the second cell gate electrode 110b may include polysilicon doped with impurities, tungsten, aluminum, titanium, tantalum, copper, titanium nitride, aluminum nitride, titanium aluminum nitride, tungsten nitride and/or tantalum nitride.

The first cell metal silicide pattern 125a and the second cell metal silicide pattern 125b may be disposed on the control gate 110a and the second cell gate electrode 110b, respectively. The first and the second cell metal silicide patterns 125a and 125b may include a metal silicide, e.g., cobalt silicide (CoSix), titanium silicide (TiSix), tungsten silicide (WSiX) and/or tantalum silicide (TaSix). The first and the second hard masks 126a and 126b may be positioned on the first and the second cell metal silicide patterns 125a and 125b, respectively. Each of the first and the second hard masks 126a and 126b may include a nitride, an oxide and/or an oxynitride. For example, each of the first and the second hard masks 126a and 126b may include silicon nitride, silicon oxide and/or silicon oxynitride.

The first and the second cell gate spacers 135 and 136 may be located on sidewalls of the first and the second cell gate stacks 131. The first cell gate spacer 135 may be provided on sidewalls of the first tunnel insulation layer pattern 102a, the memory gate structure 140a, the first cell metal silicide pattern 125a and the first hard mask 126a. The second cell gate spacer 136 may be disposed on sidewalls of the second tunnel insulation layer pattern 102b, the selection gate structure 140b, the second cell metal silicide pattern 125b and the second hard mask 126b. The first and the second cell gate spacers 135 and 136 may include a nitride or an oxynitride. For example, the first and the second cell gate spacers 135 and 136 may include silicon nitride or silicon oxynitride.

The logic transistor in the logic area II may include a logic gate structure 118, a logic gate spacer 120, first source/drain extension regions 116, and first source/drain regions 122. The logic gate structure 118 may have a gate insulation layer pattern 108a and a logic gate structure 111. The logic transistor may include a second metal silicide pattern 124a and third metal silicide patterns 124b.

A blocking pattern 126c may be disposed in the logic area II to cover the logic transistor. The blocking pattern 126c may include an oxide, a nitride and/or an oxynitride. For example, the blocking pattern 126c may include silicon oxide, silicon nitride and/or silicon oxynitride. The blocking pattern 126c may have a thickness that sufficiently covers the logic gate structure 118. In example embodiments, the blocking pattern 126c may include a material substantially the same as or substantially similar to those of the first and the second hard masks 126a and 126b.

The gate insulation layer pattern 108a may include an oxide or a metal oxide. For example, the gate insulation layer pattern 108a may include silicon oxide, hafnium oxide, zirconium oxide, titanium oxide and/or tantalum oxide. The gate insulation layer pattern 108a may have a thickness different from that of the first tunnel insulation layer pattern 102a or the second tunnel insulation layer pattern 102b. For example, the gate insulation layer pattern 108a may be substantially thicker than the first tunnel insulation layer pattern 102a and the second tunnel insulation layer pattern 102b. The logic gate structure 111 may be positioned on the gate insulation layer pattern 108a. The logic gate structure 111 may include doped polysilicon, a metal and/or a metal compound. For example, the logic gate structure 111 may include polysilicon doped with impurities, tungsten, titanium, aluminum, tantalum, tungsten nitride, titanium nitride and/or aluminum nitride.

The logic gate spacer 120 may be provided on a sidewall of the logic gate structure 118. The logic gate spacer 120 may be disposed on sidewalls of the gate insulation layer pattern 108a and the logic gate electrode 111. The logic gate spacer 120 may include a nitride, e.g., silicon nitride, or an oxynitride, e.g., silicon oxynitride. The first source/drain extension regions 116 may be located on portions of the logic area I beneath the logic gate spacer 120. The first source/drain regions 122 may be provided adjacent to the first source/drain extension regions 116. The first source/drain regions 122 may have impurity concentrations relatively higher than those of the first source/drain extension regions 116.

The second and the third metal silicide patterns 124a and 124b may be formed on the logic gate electrode 111 and the first source/drain extension regions 122, respectively. Each of the second and the third metal silicide patterns 124a and 124b may include cobalt silicide, titanium silicide, tungsten silicide and/or tantalum silicide. The memory and the selection transistors may further include second source/drain extension regions 134 and second source/drain regions 138. The second source/drain extension regions 134 may be disposed on portions of the cell area I beneath the first and the second cell gate spacers 135 and 136. The second source/drain regions 138 may be located adjacent to the second source/drain extension regions 134. The second source/drain regions 138 may make contact with the second source/drain extension regions 134. The second source/drain regions 138 may also have impurity concentrations relatively higher than those of the second source/drain extension regions 134. However, metal silicide patterns may not be provided on the second source/drain regions 138 in the cell area I.

In example embodiments, the memory and the selection transistors may be higher than a height of the logic transistor. The memory transistor may have a height substantially the same as or substantially similar to that of the selection transistor. The memory gate structure 140a may have a width substantially smaller than a width of the selection gate structure 140b. When the selection gate structure 140b has a relatively small width, a short channel effect may occur in the selection transistor. If the short channel effect is generated in the selection transistor, the selection transistor may not be properly operated, so that a failure of the embedded semiconductor device may be caused. Thus, the selection gate structure 140b may have a desired width considering the short channel effect.

The width of the memory gate structure 140a may not effect an operation of the memory transistor. Therefore, the memory gate structure 140a may have the width relatively smaller than that of the selection gate structure 140b so as to improve an integration degree of the embedded semiconductor device. The memory gate structure 140a may have a minute or reduced width below about 100 nm. For example, the width of the memory gate structure 140a may be in a range of about 70 nm to about 90 nm.

According to example embodiments, a hard mask may be provided for forming a memory gate structure of a memory transistor in an embedded semiconductor device. For example, the memory gate structure may be formed using the hard mask as an etching mask, so that the memory gate structure may have a minute or reduced width to improve an integration degree of the embedded semiconductor device. Metal silicide patterns may be located on a logic gate structure and source/drain regions, such that a logic transistor may have a lower resistance and an increased response speed. As a result, the embedded semiconductor device may have a higher integration degree and an increased response speed.

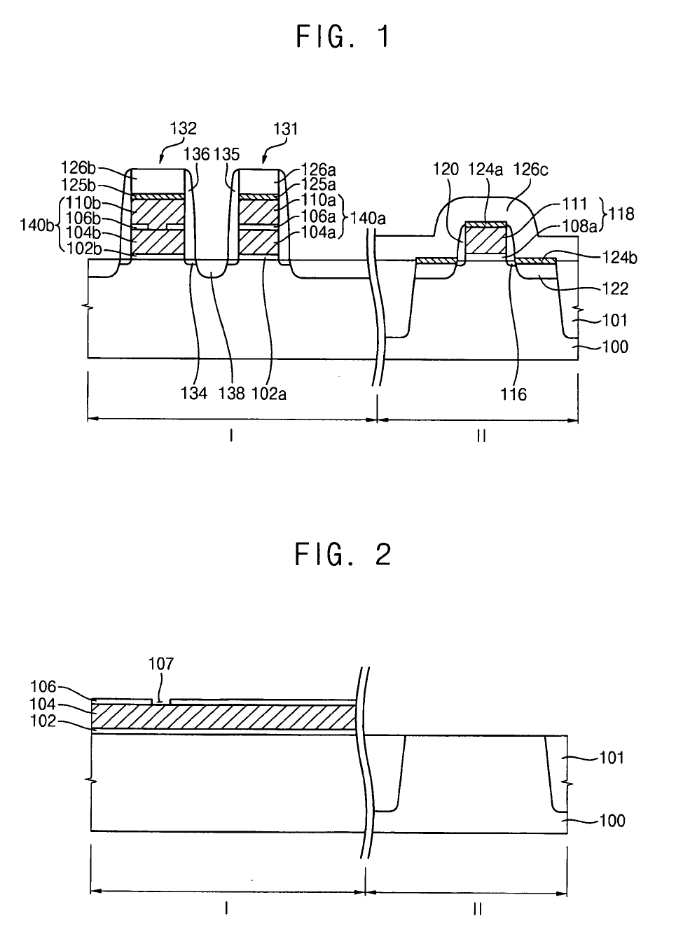

FIGS. 2 to 14 are cross-sectional views illustrating a method of manufacturing an embedded semiconductor device in accordance with example embodiments. Referring to FIG. 2, a substrate 100 having a cell area I and a logic area II may be provided. The substrate 100 may include a silicon substrate, a germanium substrate, a silicon-germanium substrate, an SOI substrate and/or a GOI substrate. Memory cells of the semiconductor device may be formed in the cell area I and logic circuits of the semiconductor device may be positioned in the logic area II. An isolation layer 101 may be formed on the substrate 100. The isolation layer 101 may be formed using an oxide, e.g., silicon oxide. For example, the isolation layer 101 may include spin on glass (SOG), undoped silicate glass (USG), flowable oxide (FOX), tetraethyl ortho silicate (TEOS), plasma enhanced-tetraethyl ortho silicate (PE-TEOS) and/or high density plasma-chemical vapor deposition (HDP-CVD) oxide. The isolation layer 101 may be formed by an isolation process, for example, a shallow trench isolation (STI) process or a thermal oxidation process. In the cell area I of the substrate 100, the isolation layer 101 may define an active region and a field region.

A tunnel insulation layer 102 may be formed on the substrate 100. The tunnel insulation layer 102 may be formed by a CVD process, an atomic layer deposition (ALD) process and/or a thermal oxidation process. The tunnel insulation layer 102 may include silicon oxide or a metal oxide having a high dielectric constant. Examples of the metal oxide in the tunnel insulation layer 102 may include hafnium oxide (HfOx), zirconium oxide (ZrOx), tantalum oxide (TaOx), aluminum oxide (AlOx) and/or titanium oxide (TiOx). In example embodiments, the tunnel insulation layer 102 may include silicon oxide formed through the thermal oxidation process.

A first conductive layer 104 may be formed on the tunnel insulation layer 102. The first conductive layer 104 may be formed using polysilicon, a metal and/or a metal compound. For example, the first conductive layer 104 may include polysilicon doped with impurities, titanium (Ti), tantalum (Ta), tungsten (W), aluminum (Al), titanium nitride (TiNx), tungsten nitride (WNx), tantalum nitride (TaNx), aluminum nitride (AlNx) and/or titanium aluminum nitride (TiAlxNy). These may be used alone or in a mixture thereof. The first conductive layer 104 may be formed by a CVD process, a sputtering process, an ALD process and/or an evaporation process.

A dielectric layer 106 may be formed on the first conductive layer 104. The dielectric layer 106 may include a metal oxide that has a dielectric constant higher than that of silicon oxide. For example, the dielectric layer 106 may be formed using aluminum oxide, hafnium oxide, zirconium oxide, titanium oxide and/or tantalum oxide. These may be used alone or in a mixture thereof. Alternatively, the dielectric layer 106 may have a multi layer structure that includes at least one oxide film and at least one nitride film. For example, the dielectric layer 106 may have an oxide/nitride/oxide (ONO) structure. The dielectric layer 106 may be formed through a CVD process, an ALD process, a sputtering process and/or an evaporation process.

A first photoresist pattern (not illustrated) may be provided on the dielectric layer 106 in the cell area I of the substrate 100. For example, the first photoresist pattern may cover first portions of the dielectric layer 106, the first conductive layer 104 and the tunnel insulation layer 102 in the cell area I. Thus, second portions of the dielectric layer 106, the first conductive layer 104 and the tunnel insulation layer 102 may be exposed in the logic area II.

Using the first photoresist pattern as an etching mask, the exposed second portions of the dielectric layer 106, the first conductive layer 104 and the tunnel insulation layer 102 in the logic area II may be etched, so that the dielectric layer 106, the first conductive layer 104 and the tunnel insulation layer 102 may remain only in the cell area I. An opening 107 may be formed through the dielectric layer 106 by partially etching the dielectric layer 106. The opening 107 may expose a portion of the first conductive layer 104. A selection transistor of the semiconductor device may be formed on a position where the opening 107 is provided.

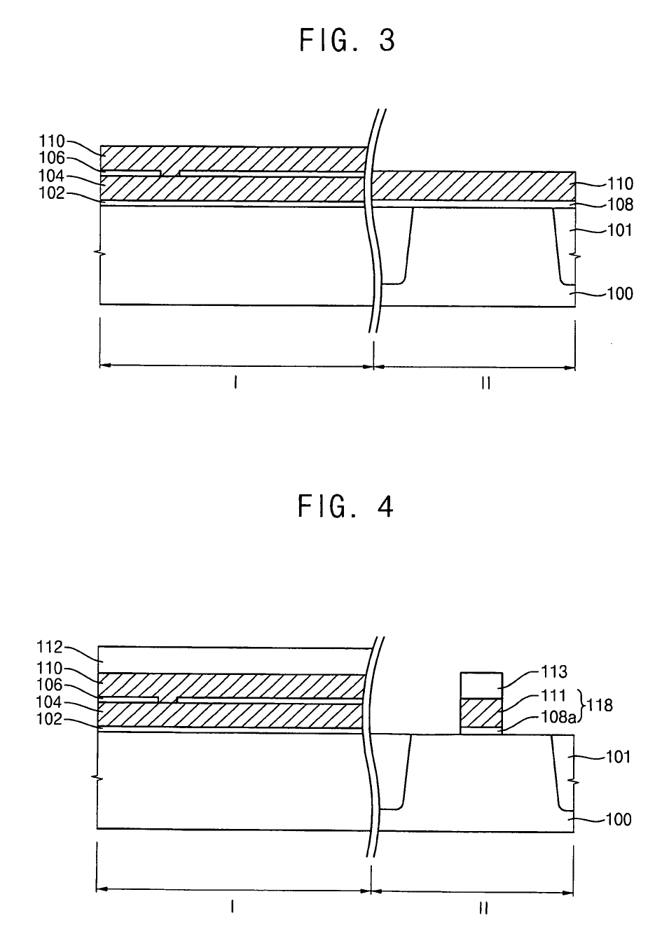

Referring to FIG. 3, a gate insulation layer 108 may be formed on the logic area II of the substrate 100. The gate insulation layer 108 may be formed using silicon oxide by a CVD process, a thermal oxidation process and/or an ALD process. Alternatively, the gate insulation layer 108 may include a metal oxide, e.g., hafnium oxide, zirconium oxide, aluminum oxide, titanium oxide and/or tantalum oxide formed through a CVD process, an ALD process, a sputtering process and/or an evaporation process. In example embodiments, the gate insulation layer 108 may have a thickness different from that of the tunnel insulation layer 102 in the cell area I. For example, the gate insulation layer 108 may have a thickness larger than that of the tunnel insulation layer 102.

A second conductive layer 110 may be formed on the dielectric layer 106 in the cell area I and the gate insulation layer 108 in the logic area II. The second conductive layer 110 may be formed using polysilicon, a metal and/or a metal compound. For example, the second conductive layer 110 may include polysilicon doped with impurities, titanium, tungsten, aluminum, tantalum, titanium nitride, aluminum nitride, tungsten nitride, tantalum nitride and/or titanium aluminum nitride. Additionally, the second conductive layer 110 may be formed by an LPCVD process, a sputtering process, an ALD process and/or an evaporation process. In example embodiments, the second conductive layer 110 may be patterned to provide a control gate 110a (see FIG. 11) of a memory transistor and a first cell gate electrode 104b (see FIG. 11) of the selection transistor in the cell area I. In the logic area II, the second conductive layer 110 may be patterned to from a logic gate electrode 111 (see FIG. 4) of a logic transistor.

Referring to FIG. 4, a second photoresist pattern 112 and a third photoresist pattern 113 may be provided in the cell area I and the logic area II, respectively. The second photoresist pattern 112 may cover a first portion of the second conductive layer 110 in the cell area I, and the third photoresist pattern 113 may be located on a second portion of the second conductive layer 110 in the logic area II. The second portion of the second conductive layer 110 and the gate insulation layer 108 may be etched using the third photoresist pattern 113 as an etching mask. A logic gate structure 1 18 may be formed in the logic area II. The logic gate structure 118 may include a gate insulation layer pattern 108a and the logic gate electrode 111. Because the second photoresist pattern 112 protects the first portion of the second conductive layer 110 in the cell area I, the second conductive layer 110 in the cell area I may not be etched while forming the logic gate structure 118 in the logic area II. After forming the logic gate structure 118 in the logic area II, the second and the third photoresist patterns 112 and 113 may be removed from the substrate 100. The second and the third photoresist patterns 112 and 13 may be removed by an ashing process and/or a stripping process.

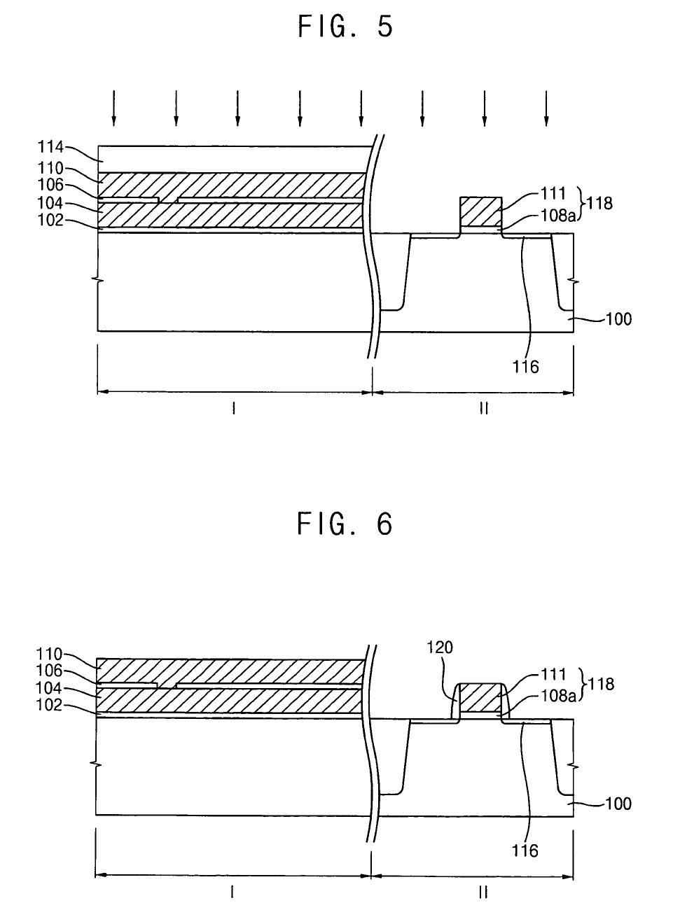

Referring to FIG. 5, a fourth photoresist pattern 114 may be formed on the first portion of the second conductive layer 110 in the cell area I. Thus, the logic area II including the logic gate structure 118 formed thereon may be exposed by the fourth photoresist pattern 114. Using the fourth photoresist pattern 114 and the logic gate structure 118 as implantation masks, impurities may be doped into portions of the logic area I adjacent to the logic gate structure 118. First source/drain extension regions 116 may be formed adjacent to the logic gate structure 118. In example embodiments, the first source/drain extension regions 116 may be formed in the logic area II without forming the fourth photoresist pattern 114 to simplify manufacturing processes for the semiconductor device.

While implanting the impurities for forming the first source/drain extension regions 116, the impurities may be doped into the logic gate electrode 111 of the logic gate structure 118. Thus, a process for doping impurities into the logic gate electrode 111 may be omitted when the logic gate electrode 111 includes polysilicon. After forming the first source/drain extension regions 116, the fourth photoresist pattern 114 may be removed by an ashing process and/or a stripping process.

Referring to FIG. 6, a first insulation layer (not illustrated) may be formed on the first portion of the second conductive layer 110 in the cell area I and on the logic area II to cover the logic gate structure 118. The first insulation layer may be formed using a nitride or an oxynitride. For example, the first insulation layer may include silicon oxide or silicon oxynitride. The first insulation layer may be formed by a CVD process, a PECVD process and/or an ALD process. The first insulation layer may be etched to form a logic gate spacer 120 on a sidewall of the logic gate structure 118. For example, the logic gate spacer 120 may be provided on sidewalls of the gate insulation layer pattern 108a and the logic gate electrode 111. The logic gate spacer 120 may be formed by an anisotropic etching process.

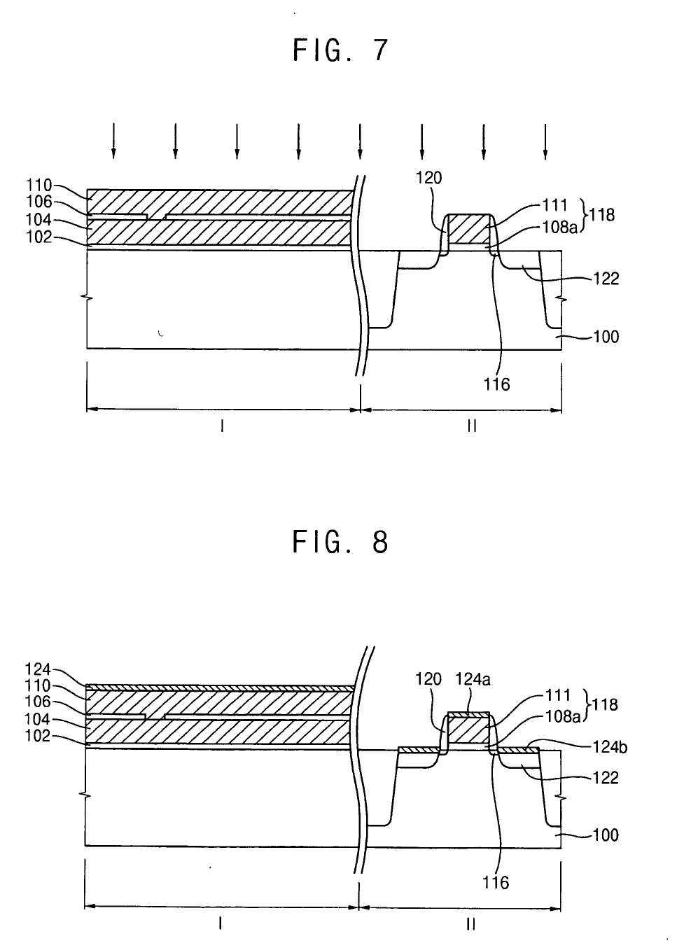

Referring to FIG. 7, impurities may be doped into portions of the logic area II near the logic gate structure 118 using the logic gate structure 118 and the logic gate spacer 120 as implantation masks, so that first source/drain regions 122 may be formed in the logic area II. The first source/drain extension regions 116 may remain beneath the logic gate spacer 120. Each of the first source/drain regions 122 may have an impurity concentration higher than that of each of the first source/drain extension regions 116.

The impurities may be doped into the first portion of the second conductive layer 120 while forming the first source/drain regions 122. Accordingly, a process for doping impurities into the second conductive layer 120 may be omitted when the second conductive layer 120 is formed using polysilicon. In example embodiments, an additional photoresist pattern (not illustrated) may be provided on the first portion of the second conductive layer 120 before forming the first source/drain regions 122. The additional photoresist pattern may serve an implantation mask together with the logic gate structure 118 and the logic gate spacer 120.

Referring to FIG. 8, a metal layer (not illustrated) may be formed on the first portion of the second conductive layer 120 and on the logic area II to cover the logic gate structure 118 and the first source/drain regions 122. The metal layer may be conformally formed on the logic gate structure 118 and the first source/drain regions 122 in the logic area II. The metal layer may include titanium, cobalt (Co), tantalum and/or tungsten. The metal layer may be formed by a CVD process, a sputtering process, an ALD process and/or an evaporation process. After a silicidation process is performed about the metal layer to form a metal silicide layer on the first portion of the second conductive layer 110, the logic gate structure 118 and the first source/drain regions 122, an unreacted portion of the metal layer may be removed from the logic area II. In the silicidation process, metal in the metal layer may react with silicon included in the second conductive layer 110, the logic gate structure 118 and the first source/drain regions 122, so that the metal silicide layer may be formed on the second conductive layer 110, the logic gate structure 118 and the first source/drain regions 122.

Accordingly, a first metal silicide pattern 124, a second metal silicide pattern 124a and third metal silicide patterns 124b may be formed in the cell area I and the logic area II. The first metal silicide pattern 124 may be provided on the first portion of the second conductive layer 120, and the second metal silicide pattern 124a may be positioned on the logic gate electrode 111. The third metal silicide patterns 124b may be located on the first source/drain regions 122, respectively. The first, the second and the third metal silicide patterns 124, 124a and 124b may include titanium silicide (TiSix), cobalt silicide (CoSix), tungsten silicide (WSix) and/or tantalum silicide (TaSix).

When the second and the third metal silicide patterns 124a and 124b are formed in the logic area II, the logic transistor may be provided in the logic area II. The logic transistor may include the logic gate structure 118, the logic gate spacer 120, the first source/drain extension regions 116, the first source/drain regions 122, the second metal silicide pattern 124a and the third metal silicide patterns 124b. Because the logic transistor includes the second metal silicide pattern 124a, the logic transistor may have a decreased gate resistance. The logic transistor may have a decreased contact resistance between the first source/drain regions 122 and a contact (not illustrated) because the third metal silicide patterns 124b may be provided on the first source/drain regions 122. Therefore, the logic transistor may have an increased response speed and improved electrical characteristics.

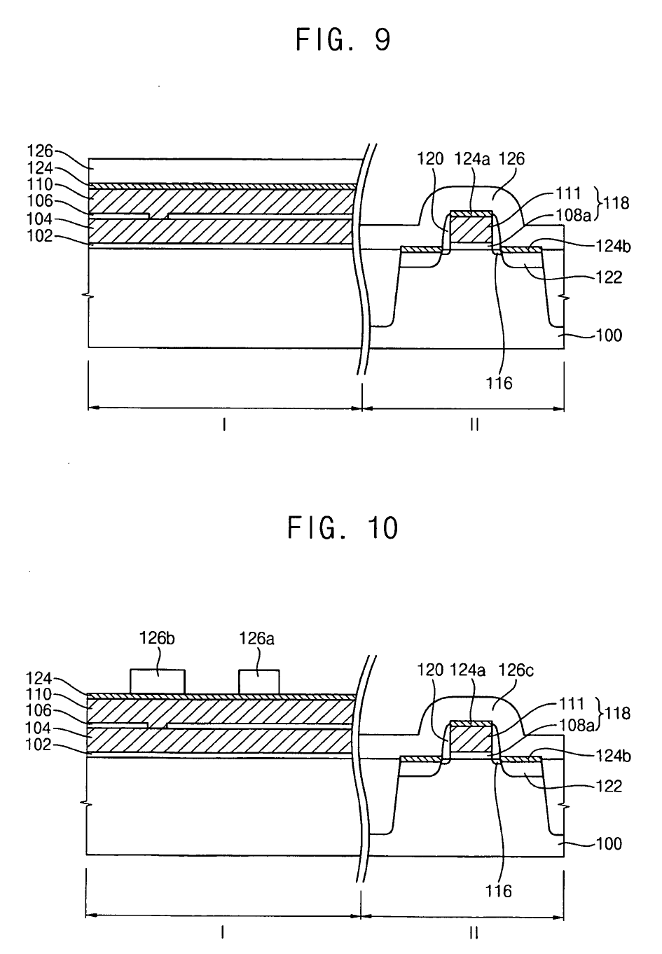

Referring to FIG. 9, a hard mask layer 126 may be formed on the cell and the logic areas I and II of the substrate 100. For example, the hard mask layer 126 may be formed on the first metal silicide pattern 124 in the cell area I. In the logic area II, the hard mask layer 126 may be formed on the substrate 100 to cover the logic transistor. Thus, the hard mask layer 126 may be formed along a profile of the logic transistor. The hard mask layer 126 may be formed using an oxide, a nitride or an oxynitride. For example, the hard mask layer 126 may include silicon oxide, silicon nitride or silicon oxynitride. In example embodiments, the hard mask layer 126 may be formed using silicon oxide by a CVD process. The hard mask layer 126 may have a thickness of about 1,000 Å to about 3,000 Å measured from an upper face of the first metal silicide pattern 124. However, the thickness of the hard mask layer 126 may vary in accordance with thicknesses of layers formed in the cell area I.

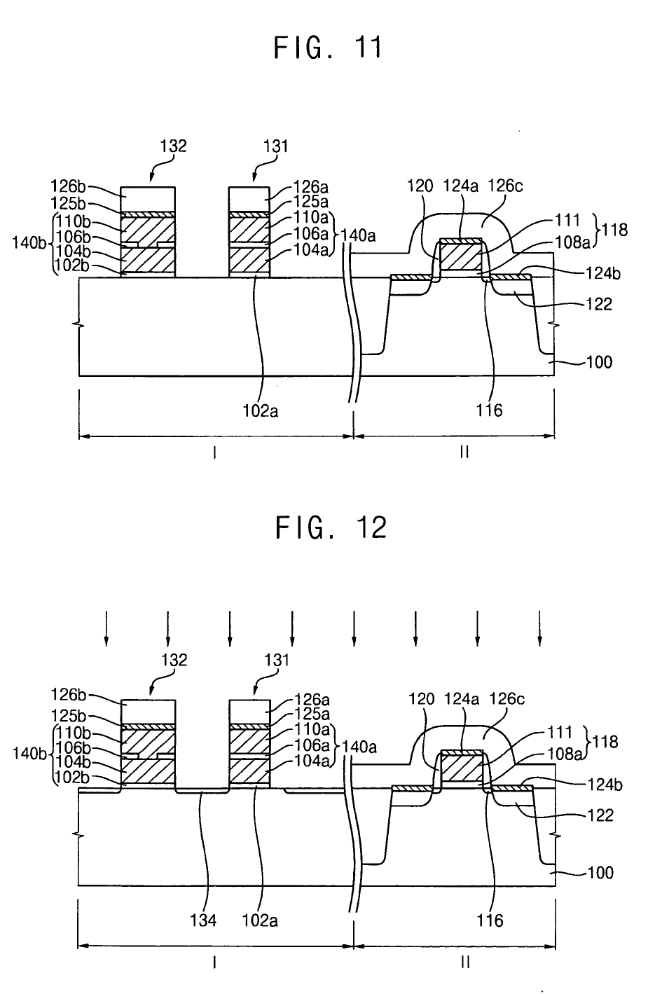

Referring to FIG. 10, a fifth photoresist pattern (not illustrated) may be provided on the hard mask layer 126, and the hard mask layer 126 may be etched using the fifth photoresist pattern as an etching mask. A first hard mask 126a, a second hard mask 126b and a blocking pattern 126c may be provided. The first and the second hard masks 126a and 126b may be positioned on the first metal silicide pattern 124 in the cell area I. The blocking pattern 126c covering the logic transistor may be located in the logic area II. The blocking pattern 126c may protect the logic transistor while successive implanting processes. The first and the second hard masks 126a and 126b may serve as etching masks for forming a memory gate structure 140a (see FIG. 11) and a selection gate structure 140b (see FIG. 11) in the cell area I.

In example embodiments, each of the first and the second hard masks 126a and 126b may have a line shape extending on the first metal silicide pattern 124 in the cell area I. The first and the second hard masks 126a and 126b may be alternatively disposed on the first metal silicide pattern 124 in parallel. The second mask 126b may have a width larger than a width of the first mask 126a because the selection gate structure 140b may have a width wider than a width of the memory gate structure 140a. The first hard mask 126a may have a width below about 100 nm. For example, the first hard mask 126a may have the width of about 70 nm to about 90 nm.

Referring to FIG. 11, the first metal silicide pattern 124, the second conductive layer 120, the dielectric layer 106, the first conductive layer 104 and the tunnel insulation layer 102 may be etched using the first and the second hard masks 126a and 126b as the etching masks. Accordingly, a first cell gate stack 131 and a second cell gate stack 132 may be formed in the cell area I. The first cell gate stack 131 may include a first tunnel insulation layer pattern 102a, the memory gate structure 140a and a first cell metal silicide pattern 125a. The memory gate structure 140a may include a floating gate 104a, a first dielectric layer pattern 106a and a control gate 110a. The second cell gate stack 132 may include a second tunnel insulation layer pattern 102b, the selection gate structure 140b and a second cell metal silicide pattern 125b. The selection gate structure 140b may include a first cell gate electrode 104b, a second dielectric layer pattern 106b and a second cell gate electrode 110b. The second cell gate electrode 110b may partially make contact with the first cell gate electrode 104b because the opening 107 formed through the second dielectric layer pattern 106b may expose the first cell gate electrode 104b as described with reference to FIG. 2.

In example embodiments, the first and the second cell gate stacks 131 and 132 may be formed using the first and the second hard masks 126a and 126b as the etching masks. Each of the first and the second hard masks 126a and 126b may have an etching selectivity relative to various patterns of the first and the second cell gate stacks 131 and 132. Thus, the first and the second hard mask 126a and 126b may not be consumed while forming the first and the second cell gate stacks 131 and 132 in the cell area I. As a result, the first and the second cell gate stacks 131 and 132 may have desired profiles. For example, each of the first and the second cell gate stacks 131 and 132 may have a substantially vertical profile. In example embodiments, each of the first and the second cell gate stacks 131 and 132 may be higher than the logic gate structure 118 in the logic area II. Thus, the conventional photoresist patterns may not be employed as the etching masks for forming the first and the second cell gate stacks 131 and 132. When the first and the second cell gate stacks 131 and 132 are formed using the first and the second hard masks 126a and 126b having the line shapes, the first and the second cell gate stacks 131 and 132 may additionally have desired minute or reduced widths, respectively.

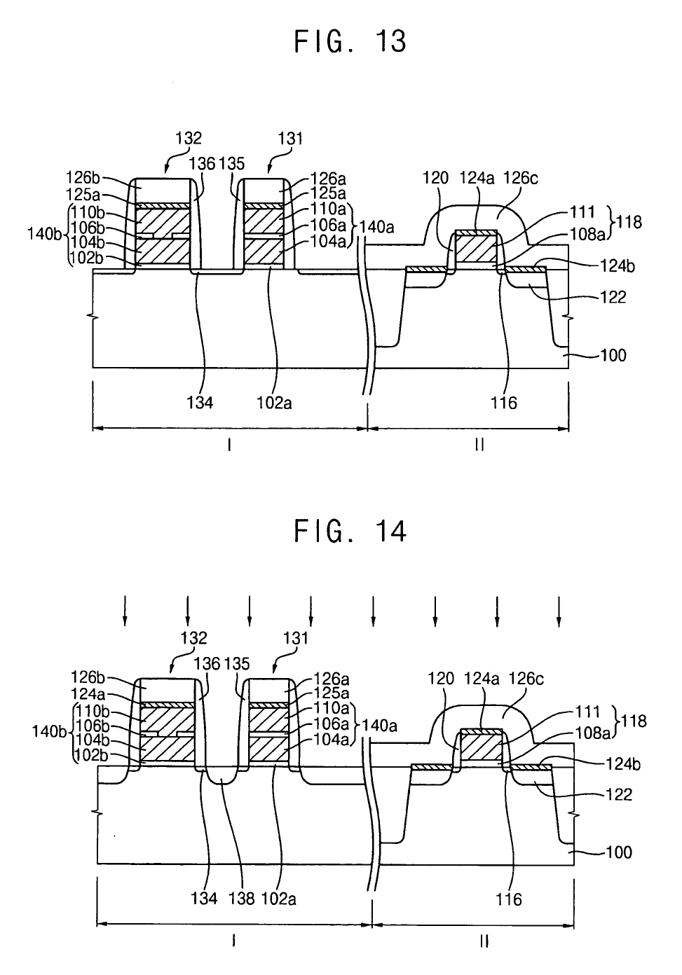

Referring to FIG. 12, using the memory gate structure 140a, the selection gate structure 140b, the first hard mask 126a and the second hard mask 126b as implantation masks, impurities may be doped into portions of the cell area I adjacent to the memory and selection gate structures 140a and 140b. Second source/drain extension regions 134 may be formed in the cell area I. Because the blocking pattern 126c covers the logic area II, the impurities may not be implanted into the logic area II while forming the second source/drain extension regions 134 in the cell area I.

Referring to FIG. 13, a second insulation layer (not illustrated) may be formed on the cell area I and the logic area II. In the cell area I, the second insulation layer may cover the first and the second cell gate stacks 131 and 132. The second insulation layer may be positioned on the blocking pattern 126c in the logic area II. The second insulation layer may be formed using a nitride or an oxynitride by a CVD process, an LPCVD process and/or a PECVD process. For example, the second insulation layer may include silicon nitride or silicon oxynitride. The second insulation layer may be etched to form a first cell gate spacer 135 and a second cell gate spacer 136 on a sidewall of the first cell gate stack 131 and a sidewall of a second cell gate stack 132, respectively. The first and the second cell gate spacers 135 and 136 may be formed by an anisotropic etching process. A portion of the second insulation layer on the blocking pattern 126c may be completely removed from the logic area II.

In example embodiments, each of the first and the second cell gate spacers 135 and 136 may have a width different from the logic gate spacer 120. For example, the first and the second cell gate spacers 135 and 136 may have widths smaller than a width of the logic gate spacer 120. The first and the second cell gate spacers 135 and 136 may serve as implantation masks for forming second source/drain regions 138 in the cell area I.

When the logic gate spacer 120 has the width different from the widths of the first and the second cell gate spacers 135 and 136, a distance between the logic gate structure 118 and the first source/drain regions 122 may be different from a distance between the first source/drain regions 138 and the memory gate structure 140a or the selection gate structure 140b. For example, the distance between the logic gate structure 118 and the first source/drain regions 122 may be adjusted by the logic gate spacer 120, and also, distance between the first source/drain regions 138 and the memory gate structure 140a or the selection gate structure 140b may be controlled by the first and the second cell gate spacers 135 and 136.

Referring to FIG. 14, impurities may be doped into portions of the cell area I adjacent to the memory gate structure 140a and the selection gate structure 140b using the first cell gate spacer 135, the second cell gate spacer 136, the first hard mask pattern 126a and the second hard mask pattern 126b as implantation masks. Accordingly, the second source/drain regions 138 may be provided on the portion of the cell area I adjacent to the memory gate structure 140a and the selection gate structure 140b. While forming the second source/drain regions 138 in the cell area I, the impurities may not be implanted into the logic area II because the blocking pattern 126c may cover the logic area II.

In example embodiments, additional implantation masks may be required on the logic area II in forming the second source/drain extension regions 134 and the second source/drain regions 138 because the blocking pattern 126c may cover the logic area II. Further, the blocking pattern 126c may be simultaneously formed together with the first and the second hard masks 126a and 126b. An additional process for forming the blocking pattern 126c in the logic area II may not be required. Therefore, the manufacturing processes for the semiconductor device may be simplified to thereby reduce the manufacturing cost and to improve a productivity of the semiconductor device. In example embodiments, an insulation interlayer (not illustrated) and the contact may be formed over the substrate 100 without removing the blocking pattern 126c from the logic area II of the substrate 100. The insulation interlayer may have a reduced thickness because the blocking pattern 126c may serve as another insulation interlayer in the logic area II.

As described above, the memory and the selection transistors may be formed in the cell area I of the substrate 100, and the logic transistor may be provided in the logic area II of the substrate 100, thereby forming the embedded semiconductor device on the substrate 100. The embedded semiconductor device may include the memory gate structure 140a having the minute or reduced width and the cell gate stacks 131 and 132 having desirable profiles. Because the metal silicide patterns 124a and 124b are formed in the logic area II, the logic transistor may be operated with an increased response speed.

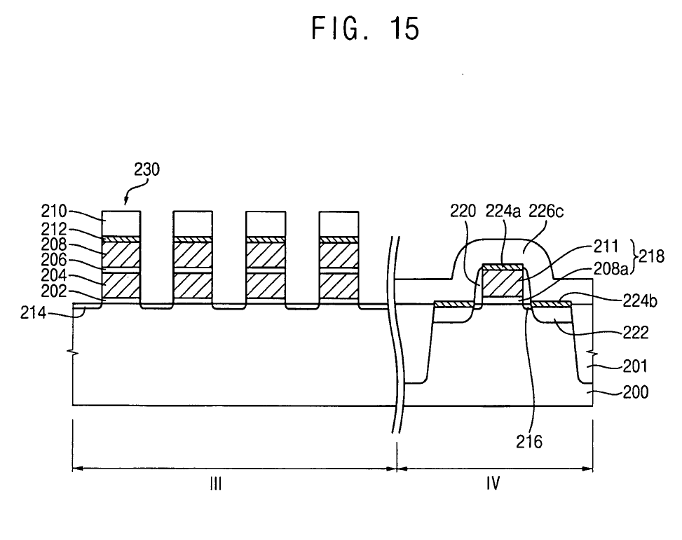

FIG. 15 is a cross-sectional view illustrating an embedded semiconductor device in accordance with example embodiments. The embedded semiconductor device illustrated in FIG. 15 may include unit cells of a NAND type flash memory device and a logic transistor for a logic circuit. In FIG. 15, “III” denotes a cell area of a substrate 200 and “IV” indicates a logic area of the substrate 200. Referring to FIG. 15, the embedded semiconductor device may be disposed on the substrate 200 having the cell area III and the logic area IV An isolation layer 201 may be provided on the substrate 200 to define an active region and a field region.

A plurality of memory transistors may be formed in the cell area III of the substrate 200. The memory transistors in the cell area III may be electrically connected to one another in parallel. In example embodiments, the embedded semiconductor device may further include a string selection transistor (not illustrated) and a ground selection transistor (not illustrated). The string selection transistor may be disposed adjacent to one peripheral memory transistor, and the ground selection transistor may be positioned adjacent to the other peripheral memory transistor. Because the unit cell of the NAND type flash memory device has one memory transistor, a selection transistor may not be employed in the unit cell of the NAND type flash memory device. Each of the memory transistors may include a memory gate stack 230. The memory gate stack 230 may include a tunnel insulation layer pattern 202, a charge trapping layer pattern 204, a dielectric layer pattern 206 and a control gate 208.

The tunnel insulation layer pattern 202 may include an oxide or a metal oxide. For example, the tunnel insulation layer pattern 202 may include silicon oxide formed by a thermal oxidation process or a CVD process. Alternatively, the tunnel insulation layer pattern 202 may include hafnium oxide, zirconium oxide, tantalum oxide, aluminum oxide or titanium oxide formed by a CVD process and/or an ALD process. The charge trapping layer pattern 204 may be positioned on the tunnel insulation layer pattern 202. The charge trapping layer pattern 204 may include a nitride or an oxynitride. For example, the charge trapping layer pattern 204 may include silicon nitride or silicon oxynitride.

The dielectric layer pattern 206 may be disposed on the charge trapping layer pattern 204. The dielectric layer pattern 206 may include a nitride, e.g., silicon nitride or a metal oxide, e.g., hafnium oxide, zirconium oxide, tantalum oxide and/or aluminum oxide. Alternatively, the dielectric layer pattern 206 may have an ONO structure that includes a lower oxide film, a nitride film and an upper oxide film. The control gate 208 may be located on the dielectric layer pattern 206. The control gate 206 may include polysilicon, a metal and/or a metal compound. For example, the control gate 206 may include polysilicon doped with impurities, tungsten, titanium, aluminum, tantalum, tungsten nitride, tantalum nitride and/or aluminum nitride.

The memory gate stack 230 may further include a cell metal silicide pattern 212 and a hard mask 210 sequentially formed on the control gate 208. The cell metal silicide pattern 212 may be provided on the control gate 206. The cell metal silicide pattern 212 may include cobalt silicide, tungsten silicide, tantalum silicide and/or titanium silicide. The hard mask 210 may be formed on the cell metal silicide pattern 212. The hard mask 210 may include an oxide, a nitride and/or an oxynitride. For example, the hard mask 210 may include silicon oxide, silicon nitride and/or silicon oxynitride. The logic transistor in the logic area IV may include a logic gate structure 218, first source/drain extension regions 216, metal silicide patterns 224a and 224b, first source/drain regions 222, and logic gate spacer 220.

The logic gate structure 218 may include a gate insulation layer pattern 208a and a logic gate electrode 211 provided on the gate insulation layer pattern 208a. The gate insulation layer pattern 208a may include silicon oxide, hafnium oxide, zirconium oxide, tantalum oxide and/or aluminum oxide. The logic gate electrode 211 may include polysilicon doped with impurities, tungsten, titanium, aluminum, tantalum, tungsten nitride, tantalum nitride and/or aluminum nitride.

The logic gate spacer 220 may be positioned on a sidewall of the logic gate structure 218. The logic gate spacer 220 may include silicon nitride or silicon oxynitride. The first source/drain extension regions 216 may be located beneath the logic gate spacer 220. The first source/drain regions 222 may be provided adjacent to the logic gate structure 118. The first source/drain regions 222 may make contact with the first source/drain extension regions 216, respectively. The first source/drain regions 222 may have impurity concentrations higher than those of the first source/drain extension regions 216. The metal silicide patterns 224a and 224b may be formed on the logic gate electrode 211 and the first source/drain regions 222. Each of the metal silicide patterns 224a and 224b may include cobalt silicide, tungsten silicide, tantalum silicide and/or titanium silicide.

A blocking pattern 226c may be provided in the logic area IV to fully cover the logic gate structure 118 and the first source/drain regions 222. The blocking pattern 226c may include a material substantially the same as that of the hard mask 210 in the cell area III. For example, the blocking pattern 226c may include silicon oxide, silicon nitride and/or silicon oxynitride. The memory transistors may further include second source/drain regions 214 adjacent to the memory gate stack 230. In example embodiments, a plurality of memory gate stacks 230 may be extended in parallel. The second source/drain regions 214 may be located between adjacent memory gate stack 230.

In example embodiments, the embedded semiconductor device may be manufactured by processes substantially the same as or substantially similar to those described with reference to FIGS. 2 to 9 except the second source/drain extension regions 134, the first cell gate spacer 135 and the second cell gate spacer 136. According to example embodiments, an embedded semiconductor device may include memory transistors and a logic transistor formed on one substrate. For example, a unit cell of a flash memory device having two transistors, a NAND type flash memory device or a NOR type flash memory device may be more easily formed in a cell area of the substrate while forming a logic circuit including the logic transistor in a logic area of the substrate. Therefore, the embedded semiconductor device may be variously employed in the flash memory device having two transistors, the NAND type flash memory device or the NOR type flash memory device.

The foregoing is illustrative of example embodiments, and is not to be construed as limiting thereof. Although a few example embodiments have been described, those skilled in the art will readily appreciate that many modifications are possible in example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. Example embodiments are defined by the following claims, with equivalents of the claims to be included therein.

What is claimed is:

1. An embedded semiconductor device comprising:
at least one cell gate stack in a cell area of a substrate;
at least one hard mask on the at least one cell gate stack;
a logic gate structure in a logic area of the substrate;
first source/drain regions adjacent to the logic gate structure;
metal silicide patterns on the logic gate structure and the first source/drain regions; and
a blocking pattern covering the logic gate structure and the first source/drain regions.

2. The embedded semiconductor device of claim 1, wherein the at least one cell gate stack comprises a first cell gate stack including a memory gate structure and a second cell gate stack including a selection gate structure.

3. The embedded semiconductor device of claim 2, wherein the memory gate structure has a width smaller than a width of the selection gate structure.

4. The embedded semiconductor device of claim 2, wherein the memory gate structure includes a floating gate, a first dielectric layer pattern and a control gate, and the selection gate structure includes a first cell gate electrode, a second dielectric layer pattern and a second cell gate electrode.

5. The embedded semiconductor device of claim 2, wherein the at least one hard mask includes a first hard mask and a second hard mask, and
the first cell gate stack comprises a first tunnel insulation layer pattern beneath the memory gate structure, a first cell metal silicide pattern on the memory gate structure and the first hard mask on the first cell metal silicide pattern, and
the second cell gate stack comprises a second tunnel insulation layer pattern beneath the selection gate structure, a second cell metal silicide pattern on the selection gate structure and the second hard mask on the second cell metal silicide pattern.

6. The embedded semiconductor device of claim 1, wherein the logic gate structure has a height smaller than a height of the at least one cell gate stack.

7. The embedded semiconductor device of claim 6, wherein the logic gate structure comprises a gate insulation layer pattern and a logic gate electrode.

8. The embedded semiconductor device of claim 1, wherein the at least one cell gate stack comprises a tunnel insulation layer pattern, a charge trapping layer pattern, a dielectric layer pattern and a control gate.

9. The embedded semiconductor device of claim 1, wherein the blocking pattern includes the same material as the at least one hard mask.

10. The embedded semiconductor device of claim 1, further comprising:
second source/drain regions adjacent to the at least one cell gate stack.

11. The embedded semiconductor device of claim 1, further comprising:
a cell gate spacer on a sidewall of the at least one cell gate stack; and
a logic gate spacer on a sidewall of the logic gate structure.

12. The embedded semiconductor device of claim 11, further comprising:
first source/drain extension regions beneath the logic gate spacer; and
second source/drain extension regions beneath the cell gate spacer.

13. A method of manufacturing an embedded semiconductor device, comprising:
forming layers of at least one cell gate stack in a cell area of a substrate;
forming a logic gate structure in a logic area of the substrate;
forming first source/drain regions adjacent to the logic gate structure;
forming metal silicide patterns on the logic gate structure and the first source/drain regions;
forming at least one hard mask on the layers of the at least one cell gate stack;
forming a blocking pattern covering the logic gate structure and the first source/drain regions; and
forming the at least one cell gate stack in the cell area by etching the layers of the at least one cell gate stack using the at least one hard mask as an etching mask.

14. The method of claim 13, wherein forming the layers of the at least one cell gate stack comprises:
forming a tunnel insulation layer on the substrate;
forming a first conductive layer on the tunnel insulation layer;
forming a dielectric layer on the first conductive layer;
removing portions of the dielectric layer, the first conductive layer and the tunnel insulation layer from the logic area of the substrate;
forming a gate insulation layer in the logic area; and
forming a second conductive layer on a remaining dielectric layer and the gate insulation layer.

15. The method of claim 14, further comprising:
forming an opening exposing the first conductive layer by partially removing the remaining dielectric layer before forming the second conductive layer.

16. The method of claim 14, wherein forming the at least one hard mask and forming the at least one cell gate stack comprise:
forming a first hard mask and a second hard mask on the second conductive layer in the cell area; and
forming a first cell gate stack and a second cell gate stack by etching the second conductive layer, the dielectric layer, the first conductive layer and the tunnel insulation layer using the first and the second hard masks as etching masks.

17. The method of claim 16, wherein forming the first cell gate stack comprises forming a first tunnel insulation layer pattern, a floating gate, a first dielectric layer pattern and a control gate, and wherein forming the second cell gate stack comprises forming a second tunnel insulation layer pattern, a first cell gate electrode, a second dielectric layer pattern and a second cell gate electrode.

18. The method of claim 17, wherein forming the first cell gate stack and forming the second cell gate stack further comprise forming a first cell metal silicide pattern on the control gate and a second cell metal silicide pattern on the second cell gate electrode.

19. The method of claim 16, further comprising:
forming a first cell gate spacer on a sidewall of the first cell gate stack; and
forming a second cell gate spacer on a sidewall of the second cell gate stack.

20. The method of claim 14, wherein forming the at least one hard mask and forming the at least one cell gate stack comprise:
forming the at least one hard mask on the second conductive layer in the cell area; and
forming the at least one cell gate stack by etching the second conductive layer, the dielectric layer, the first conductive layer and the tunnel insulation layer using the at least one hard mask as an etching mask.

21. The method of claim 20, wherein the at least one cell gate stack comprises a tunnel insulation layer pattern, a charge trapping layer pattern, a dielectric layer pattern and a control gate.

22. The method of claim 14, wherein forming the logic gate structure comprises:
forming a photoresist pattern on the second conductive layer in the logic area; and
forming a gate insulation layer pattern and a logic gate electrode by etching the second conductive layer and the gate insulation layer using the photoresist pattern as an etching mask.

23. The method of claim 13, wherein forming the at least one hard mask and forming the blocking pattern are simultaneously performed.

24. The method of claim 23, wherein forming the at least one hard mask and forming the blocking pattern comprise:
forming a hard mask layer on the layers of the at least one cell gate stack and the logic gate structure;
forming a photoresist pattern on the hard mask layer; and
etching the hard mask layer using the photoresist pattern as an etching mask.

25. The method of claim 13, further comprising:
forming second source/drain regions adjacent to the at least one cell gate stack.
